(19) United States
(12) Patent Application Publication
(10) Pub. No.: US 2024/0128424 A1
(43) Pub. Date: Apr. 18, 2024

(54) SEMICONDUCTOR DEVICE, SENSOR, AND METHOD OF MANUFACTURING SEMICONDUCTOR DEVICE

(71) Applicant: ROHM CO., LTD., Kyoto (JP)

(72) Inventor: Dai MIYAZAKI, Kyoto (JP)

(73) Assignee: ROHM CO., LTD., Kyoto (JP)

(21) Appl. No.: 18/485,684

(22) Filed: Oct. 12, 2023

(30) Foreign Application Priority Data
Oct. 14, 2022 (JP) 2022-165426

(51) Int. Cl. H01L 33/62; H01L 33/20

(52) U.S. Cl. CPC H01L 33/62; H01L 33/20; H01L 2933/0066

(57) ABSTRACT

A semiconductor device includes: a substrate; and a semiconductor element, wherein the substrate includes a base and a conductor pattern arranged on the base, the conductor pattern includes a die pad portion and first and second connection portions, the die pad portion includes first and second ends in a first direction, and third and fourth ends in a second direction, outer periphery of the die pad portion includes first and second sides in the second direction, and third and fourth sides in the first direction, a recess is formed on one of the first and second sides, the first and second connection portions are respectively connected to a first corner of the outer periphery where the second and third sides are joined, and a second corner of the outer periphery where the second and fourth sides are joined.

### CROSS-REFERENCE TO RELATED APPLICATION

This application is based upon and claims the benefit of priority from Japanese Patent Application No. 2022-165426, filed on Oct. 14, 2022, the entire contents of which are incorporated herein by reference.

### TECHNICAL FIELD

The present disclosure relates to a semiconductor device, a sensor, and a method of manufacturing the semiconductor device.

### BACKGROUND

In the related art, a semiconductor device is known. The semiconductor device includes a substrate having a base and a conductor pattern disposed on the base, and an LED (Light Emitting Diode) element.

The conductor pattern is arranged on the base. The conductor pattern includes an expansion portion, a first connection portion, and a second connection portion. The expansion portion includes a rectangular shape in a plan view. More specifically, in a plan view, the expansion portion includes a first end and a second end which are both ends in a first direction, and a third end and a fourth end which are both ends in a second direction orthogonal to the first direction. In a plan view, an outer periphery of a die pad portion includes a first side and a second side extending in the second direction, and a third side and a fourth side extending in the first direction. The first side and the second side constitute a first end and a second end, respectively, and the third side and the fourth side constitute a third end and a fourth end, respectively.

The first connection portion and the second connection portion are connected to a corner of the die pad portion where the second side and the third side are joined, and a corner of the die pad portion where the second side and the fourth side are joined, respectively. The LED element is arranged on the expansion portion with a connecting material (such as silver paste) interposed therebetween.

### BRIEF DESCRIPTION OF DRAWINGS

The accompanying drawings, which are incorporated in and constitute a part of the specification, illustrate embodiments of the present disclosure.

FIG. 1 is a plan view of a semiconductor device.

FIG. 2 is a bottom view of the semiconductor device.

FIG. 3 is a cross-sectional view taken along III-III in FIG. 1.

FIG. 4 is a schematic diagram of a sensor.

FIG. 5 is a plan view of a semiconductor device according to a first modification.

FIG. 6 is a plan view of a semiconductor device according to a second modification.

FIG. 7 is a plan view of a semiconductor device according to a third modification.

FIG. 8 is a process diagram showing a method of manufacturing a semiconductor device.

FIG. 9 is a cross-sectional view illustrating a preparation step S1.

FIG. 10 is a plan view illustrating a conductor layer patterning step S2.

FIG. 11 is a bottom view illustrating the conductor layer patterning step S2.

FIG. 12 is a plan view illustrating a semiconductor element mounting step S3.

FIG. 13 is a plan view illustrating a wire bonding step S4.

FIG. 14 is a plan view illustrating a resist forming step S5.

FIG. 15 is a cross-sectional view illustrating a resin sealing step S6.

FIG. 16 is a plan view of a semiconductor device.

FIG. 17 is a plan view of a semiconductor device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Details of an embodiment of the present disclosure will be described with reference to the drawings. The same or corresponding parts in the following drawings are designated by like reference numerals, and redundant descriptions thereof will not be repeated. The semiconductor device according to an embodiment is referred to as a semiconductor device 100.

### (Configuration of Semiconductor Device 100)

A configuration of the semiconductor device 100 will be described below.

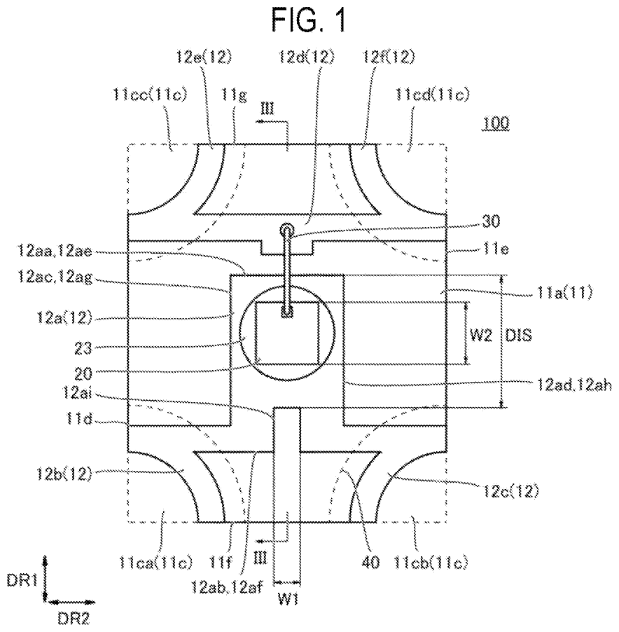

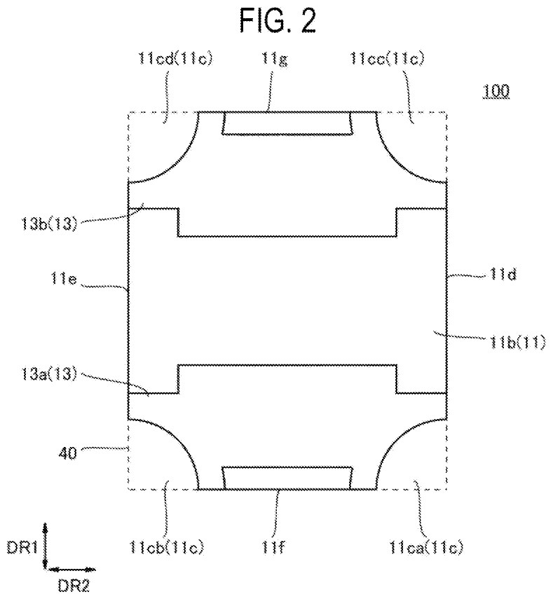

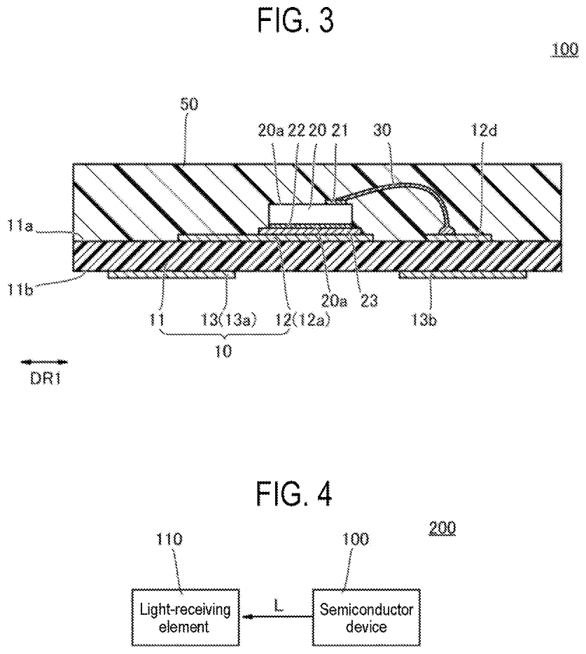

FIG. 1 is a plan view of the semiconductor device 100. In FIG. 1, illustration of a sealing resin 50 is omitted, and a resist 40 is indicated by a dotted line. FIG. 2 is a bottom view of the semiconductor device 100. FIG. 3 is a cross-sectional view taken along III-III in FIG. 1. As shown in FIGS. 1 to 3, the semiconductor device 100 includes a substrate 10, a semiconductor element 20, a bonding wire 30, a resist 40, and a sealing resin 50.

The substrate 10 includes a base 11, a conductor pattern 12, and a conductor pattern 13. The base 11 is made of an electrically insulating material. The electrically insulating material is, for example, glass epoxy. The base 11 includes a main surface 11a and a main surface 11b. The main surface 11a and the main surface 11b are end surfaces of the base 11 in its thickness direction. The main surface 11b is a surface opposite the main surface 11a. In a plan view (when viewed from the side of the main surface 11a in a direction perpendicular to the main surface 11a), a longitudinal direction of the base 11 extends in a first direction DR1.

A plurality of through-holes 11c are formed in the base 11. The through-holes 11c penetrate the base 11 in the thickness direction. The through-holes 11c are arranged at the four corners of the base 11 in a plan view. In a plan view, the outer periphery of the base 11 includes a first side 11d and a second side 11e extending in the first direction DR1, and a third side 11f and a fourth side 11g extending in a second direction DR2. The second direction DR2 is a direction orthogonal to the first direction DR1.

The through-hole 11c at the corner of the base 11 where the first side 11d and the third side 11f are joined is referred to as a through-hole 11ca, and the through-hole 11c at the corner of the base 11 where the second side 11e and the third side 11f are joined is referred to as a through-hole 11cb. The through-hole 11c at the corner of the base 11 where the first side 11d and the fourth side 11g are joined is referred to as a through-hole 11cc, and the through-hole 11c at the corner of the base 11 where the second side 11e and the fourth side 11g are joined is referred to as a through-hole 11cd.

The conductor pattern 12 is arranged on the main surface 11a. The conductor pattern 12 is made of a conductive material. The conductive material is, for example, copper (Cu). The conductor pattern 12 includes a die pad portion 12a, a connection portion 12b, and a connection portion 12c. The conductor pattern 12 further includes a bonding pad portion 12d, a connection portion 12e, and a connection portion 12f.

The die pad portion 12a includes a first end 12aa, a second end 12ab, a third end 12ac, and a fourth end 12ad in a plan view. The first end 12aa and the second end 12ab are both ends of the die pad portion 12a in the first direction DR1, and the third end 12ac and the fourth end 12ad are both ends of the die pad portion 12a in the second direction DR2.

In a plan view, the outer periphery of the die pad portion 12a is rectangular except for a portion where a recess 12ai, which will be described later, is formed. More specifically, in a plan view, the outer periphery of the die pad portion 12a includes a first side 12ae and a second side 12af extending in the second direction DR2, and a third side 12ag and a fourth side 12ah extending in the first direction DR1. The first side 12ae and the second side 12af constitute a first end 12aa and a second end 12ab, respectively. The third side 12ag and the fourth side 12ah constitute a third end 12ac and a fourth end 12ad, respectively.

The recess 12ai is formed in the second side 12af. The second side 12af is recessed toward the first side 12ae in the recess 12ai. The recess 12ai has, for example, a rectangular shape in a plan view. A distance between a bottom of the recess 12ai and a side (first side 12ae) facing the bottom is defined as a distance DIS. A width of the recess 12ai in the second direction DR2 is defined as a width W1. The width W1 is, for example, 0.2 mm or less. The width W1 may be 0.15 mm or less.

The corner of the die pad portion 12a where the second side 12af and the third side 12ag are joined is referred to as a first corner. The corner of the die pad portion 12a where the second side 12af and the fourth side 12ah are joined is referred to as a second corner. One end of the connection portion 12b is connected to the first corner of the die pad portion 12a. The other end of the connection portion 12b surrounds the through-hole 11ca. One end of the connection portion 12c is connected to the second corner. The other end of the connection portion 12c surrounds the through-hole 11cb of the die pad portion 12a.

The bonding pad portion 12d is arranged at an interval from the first side 12ae in the first direction DR1. One end of the connection portion 12e is connected to the bonding pad portion 12d. The other end of the connection portion 12e surrounds the through-hole 11cc. One end of the connection portion 12f is connected to the bonding pad portion 12d. The other end of the connection portion 12f surrounds the through-hole 11cd.

The conductor pattern 13 is arranged on the main surface 11b. The conductor pattern 13 is made of a conductive material. The conductive material is, for example, copper. The conductor pattern 13 includes a terminal portion 13a and a terminal portion 13b. In a bottom view (when viewed from the side of the main surface 11b in a direction perpendicular to the main surface 11b), the terminal portion 13a is located on the end portion of the main surface 11b near the third side 11f. In a bottom view, the terminal portion 13b is located on the end portion of the main surface 11b near the fourth side 11g. That is, the terminal portion 13a and the terminal portion 13b are arranged at an interval in the first direction DR1.

Although not shown, a conductor layer is arranged on an inner wall surface of the through-hole 11c (the through-hole 11ca, the through-hole 11cb, the through-hole 11cc, and the through-hole 11cd). The conductor layer is made of a conductive material. The conductive material is, for example, copper. The connection portion 12b is electrically connected to the terminal portion 13a by the conductive layer arranged on the inner wall surface of the through-hole 11ca, and the connection portion 12c is electrically connected to the terminal portion 13a by the conductive layer arranged on the inner wall surface of the through-hole 11cb. The connection portion 12b is electrically connected to the terminal portion 13b by the conductive layer arranged on the inner wall surface of the through-hole 11cc, and the connection portion 12c is electrically connected to the terminal portion 13b by the conductive layer arranged on the inner wall surface of the through-hole 11cd.

The semiconductor element 20 is, for example, an LED. The semiconductor element 20 is preferably an LED configured to generate infrared light. However, the semiconductor element 20 is not limited to the LED. The semiconductor element 20 may be a light-receiving element such as a phototransistor or a photodiode. The semiconductor element 20 includes a main surface 20a and a main surface 20b. The main surface 20a and the main surface 20b are end surfaces of the semiconductor element 20 in the thickness direction. The main surface 20a is a surface opposite the main surface 20b. The semiconductor element 20 includes a front surface electrode 21 on the main surface 20a and a back surface electrode 22 on the main surface 20b. When the semiconductor element 20 is an LED, the front surface electrode 21 is a cathode of the LED, and the back surface electrode 22 is an anode of the LED.

The semiconductor element 20 is arranged on the die pad portion 12a with a connecting material 23 interposed therebetween. The main surface 20b faces the die pad portion 12a with the connecting material 23 interposed therebetween. The connecting material 23 is made of a conductive material. The connecting material 23 is, for example, a conductive adhesive. The back surface electrode 22 is electrically connected to the die pad portion 12a by the connecting material 23. The semiconductor element 20 is arranged between the bottom of the recess 12ai and the first side 12ae in a plan view. The width of the semiconductor element 20 in the first direction DR1 is referred to as a width W2. The width W2 is smaller than the distance DIS. The value obtained by subtracting the width W2 from the distance DIS (difference between the distance DIS and the width W2) is preferably 0.05 mm or more and 0.40 mm or less. It is preferable that the center of the semiconductor element 20 in a plan view coincides with the center of the base 11 in a plan view.

The bonding wire 30 is made of a conductive material. The conductive material is, for example, gold (Au), copper, or the like. One end of the bonding wire 30 is bonded to the bonding pad portion 12d. The other end of the bonding wire 30 is bonded to the front surface electrode 21. Thus, the front surface electrode 21 and the bonding pad portion 12d are electrically connected. As described above, the terminal portion 13a is electrically connected to the connection portion 12b and the connection portion 12c, and the terminal portion 13b is electrically connected to the connection portion 12e and the connection portion 12f. Therefore, by applying a voltage between the terminal portion 13a and the terminal portion 13b, the semiconductor element 20 (LED) is energized, and light is generated in the semiconductor element 20.

The resist 40 is, for example, a solder resist. The resist 40 is arranged on the conductor pattern 12 so as to close the through-hole 11c. However, the conductor pattern 12 existing in a region other than the periphery of the through-hole 11c is exposed from the resist 40. The sealing resin 50 is arranged on the main surface 11a so as to cover the conductor pattern 12, the semiconductor element 20, the connecting material 23, the bonding wire 30, and the resist 40. When the semiconductor element 20 is an LED, the sealing resin 50 is preferably formed of a resin which is transparent to the light generated by the LED.

The semiconductor device 100 is used, for example, in a sensor 200. FIG. 4 is a schematic diagram of the sensor 200. As shown in FIG. 4, the sensor 200 includes a semiconductor device 100 and a light-receiving element 110. When the semiconductor element 20 is an LED, light (referred to as light L) is generated in the semiconductor element 20. The light-receiving element 110 is arranged to receive the light L. The sensor 200 is configured to perform various types of sensing operation based on a state of reception of the light L in the light-receiving element 110.

### <First Modification>

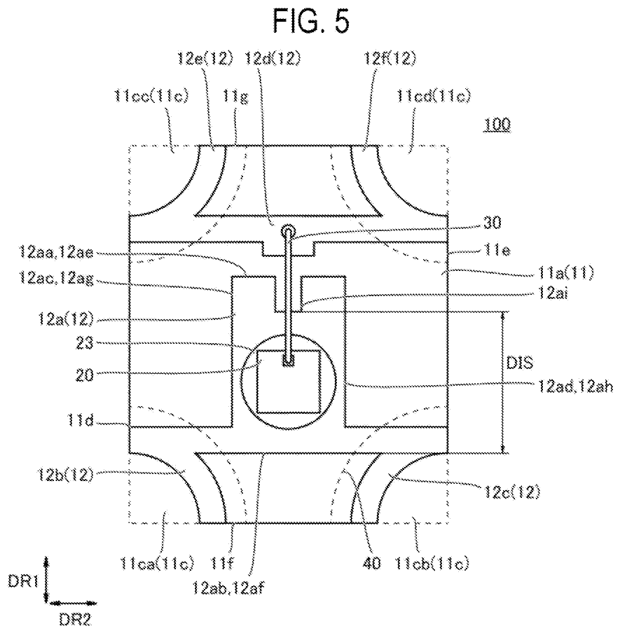

FIG. 5 is a plan view of a semiconductor device 100 according to a first modification. In FIG. 5, illustration of the sealing resin 50 is omitted, and the resist 40 is indicated by a dotted line. As shown in FIG. 5, the recess 12ai may be formed on the first side 12ae. In this case, the first side 12ae is recessed toward the second side 12af in the recess 12ai, and the semiconductor element 20 is located between the second side 12af and the recess 12ai in a plan view. That is, in the semiconductor device 100, the recess 12ai is formed on one of the first side 12ae and the second side 12af, and is recessed toward the other of the first side 12ae and the second side 12af. The semiconductor element 20 only needs to be arranged between the recess 12ai and the first side 12ae or the second side 12af in a plan view. In this case, the distance DIS is a distance between the recess 12ai and the second side 12af.

### <Second Modification and Third Modification>

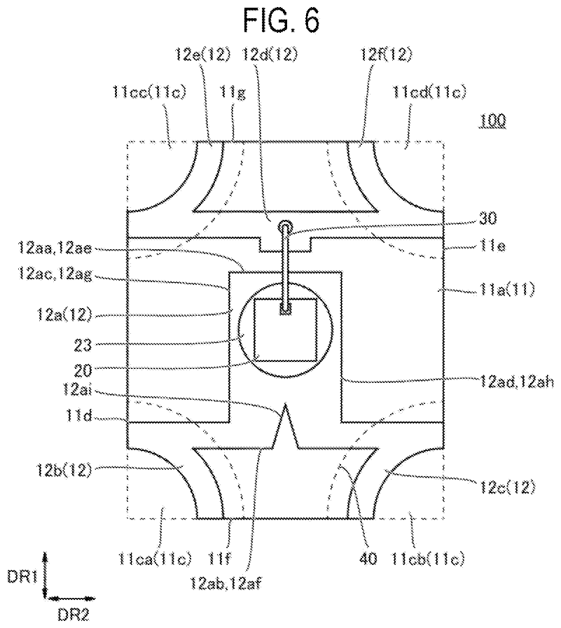

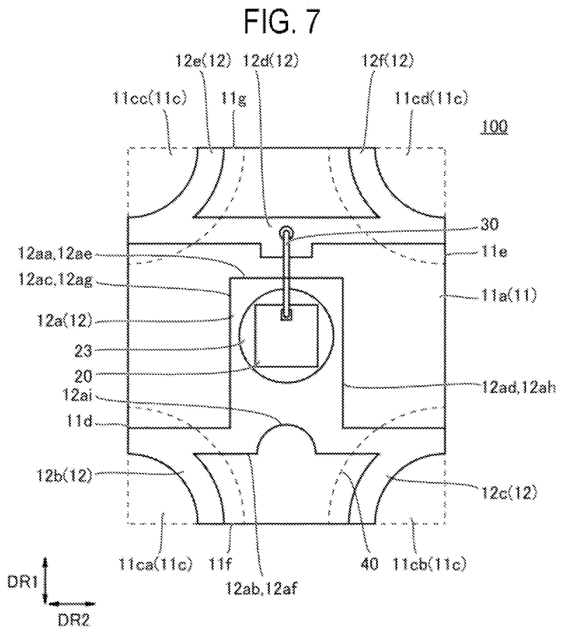

FIG. 6 is a plan view of a semiconductor device 100 according to a second modification. FIG. 7 is a plan view of a semiconductor device 100 according to a third modification. In FIGS. 6 and 7, illustration of the sealing resin 50 is omitted, and the resist 40 is indicated by a dotted line. As shown in FIGS. 6 and 7, a shape of the recess 12ai in a plan view is not limited to the rectangular shape. The recess 12ai in a plan view may be triangular (see FIG. 6) or semicircular (partially circular) (see FIG. 7).

### (Method of Manufacturing Semiconductor Device 100)

A method of manufacturing a semiconductor device 100 will be described below.

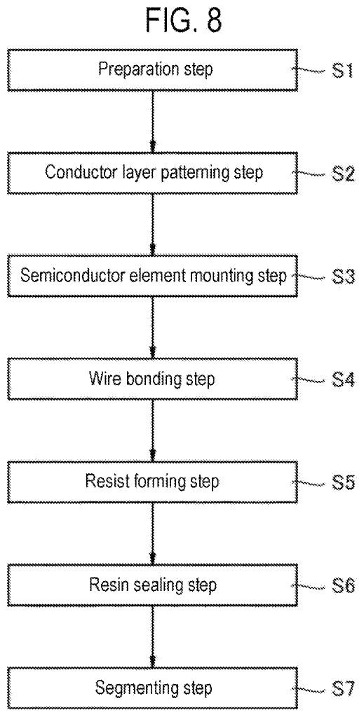

FIG. 8 is a process diagram showing a method of manufacturing the semiconductor device 100. As shown in FIG. 8, the method of manufacturing the semiconductor device 100 includes a preparation step S1, a conductor layer patterning step S2, a semiconductor element mounting step S3, a wire bonding step S4, a resist forming step S5, a resin sealing step S6, and a segmenting step S7.

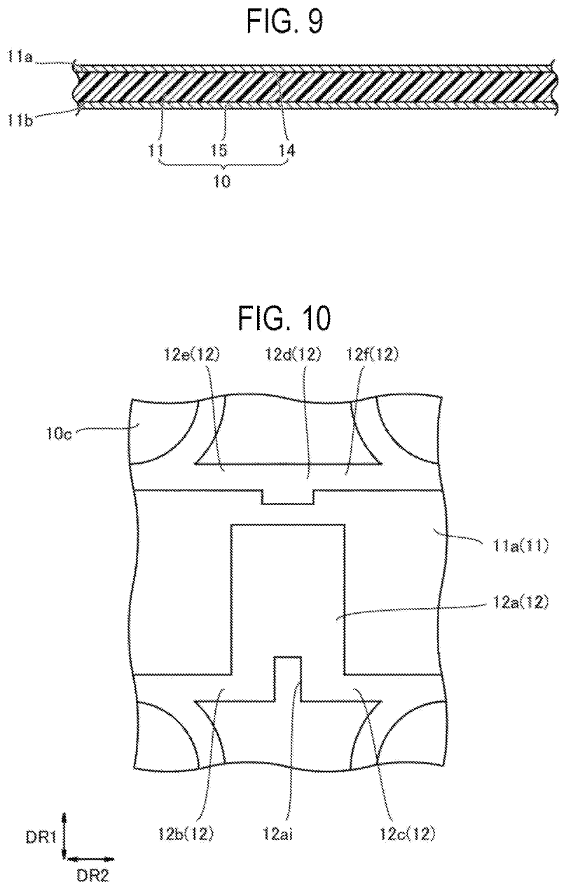

In the preparation step S1, the substrate 10 is prepared. The substrate 10 prepared in the preparation step S1 has not been segmented. FIG. 9 is a cross-sectional view illustrating the preparation step S1. As shown in FIG. 9, in the substrate 10 prepared in the preparation step S1, the conductor layer 14 is arranged on the main surface 11a, and the conductor layer 15 is arranged on the main surface 11b.

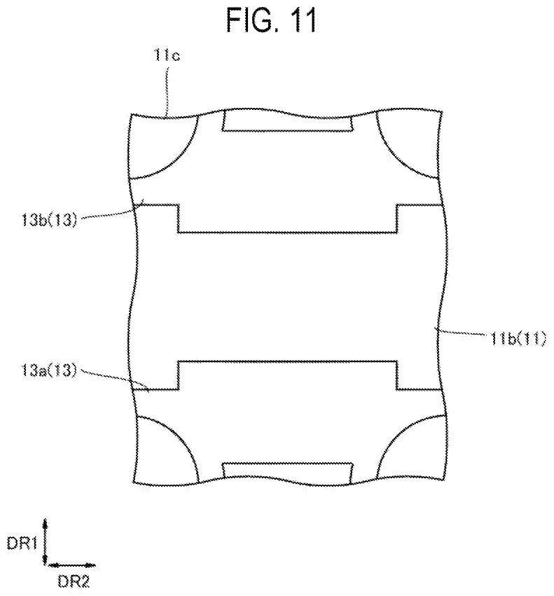

The conductor layer patterning step S2 is performed after the preparation step S1. FIG. 10 is a plan view illustrating the conductor layer patterning step S2. FIG. 11 is a bottom view illustrating the conductor layer patterning step S2. As shown in FIGS. 10 and 11, in the conductor layer patterning step S2, the conductor pattern 12 is formed by patterning the conductor layer 14, and the conductor pattern 13 is formed by patterning the conductor layer 15. The patterning of the conductor layer 14 and the conductor layer 15 is performed by etching with a resist arranged on the conductor layer 14 and the conductor layer 15 used as a mask. The recess 12ai is preferably formed during the patterning of the conductor layer 14. In other words, it is preferable that the recess 12ai is formed simultaneously with the die pad portion 12a.

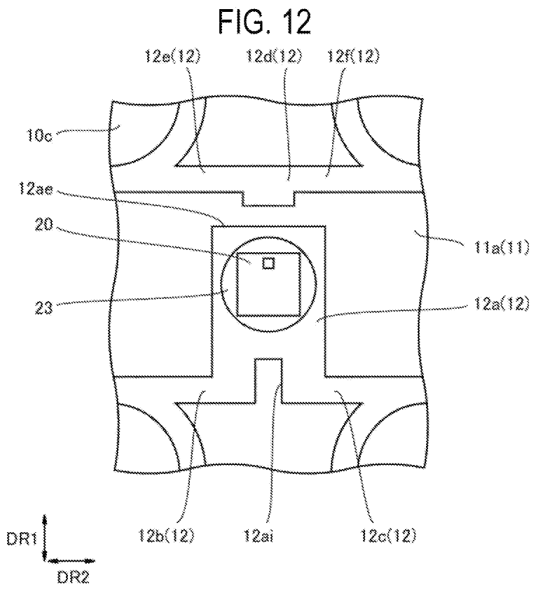

The semiconductor element mounting step S3 is performed after the conductor layer patterning step S2. FIG. 12 is a plan view illustrating the semiconductor element mounting step S3. As shown in FIG. 12, in the semiconductor element mounting step S3, the semiconductor element 20 is arranged on the die pad portion 12a. At this time, the semiconductor element 20 is arranged between the bottom of the recess 12ai and the side facing the bottom (the first side 12ae in the example of FIG. 12) in a plan view. First, in the semiconductor element mounting step S3, an uncured connecting material 23 is coated onto the die pad portion 12a. Second, the semiconductor element 20 is placed on the connecting material 23. Third, the back surface electrode 22 is joined to the die pad portion 12a by heating and hardening the connecting material 23.

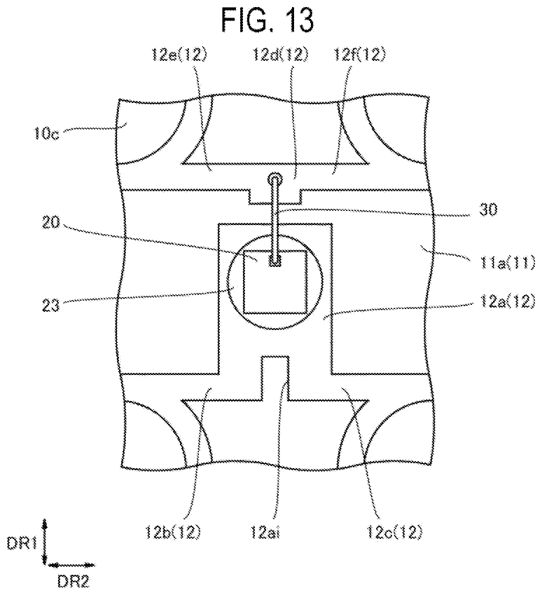

The wire bonding step S4 is performed after the semiconductor element mounting step S3. FIG. 13 is a plan view illustrating the wire bonding step S4. As shown in FIG. 13, in the wire bonding step S4, one end of the bonding wire 30 is bonded to the bonding pad portion 12d, and the other end of the bonding wire 30 is bonded to the front surface electrode 21, whereby the bonding pad portion 12d and the front surface electrode 21 are connected.

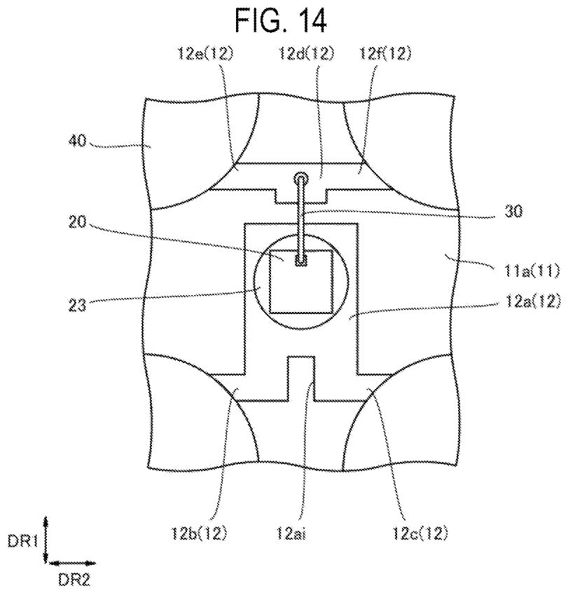

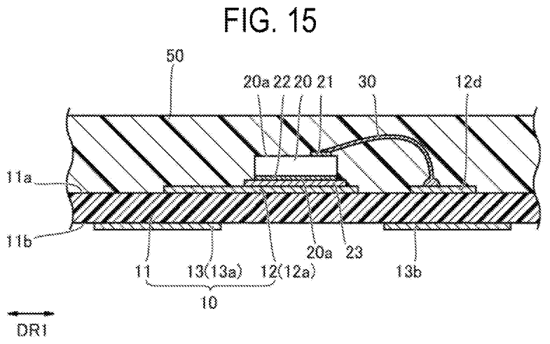

The resist forming step S5 is performed after the wire bonding step S4. FIG. 14 is a plan view illustrating the resist forming step S5. As shown in FIG. 14, in the resist forming step S5, a resist 40 is formed on the conductor pattern 12 so as to cover the through-holes 11c. The resin sealing step S6 is performed after the resist forming step S5. FIG. 15 is a cross-sectional view illustrating the resin sealing step S6. As shown in FIG. 15, in the resin sealing step S6, a sealing resin 50 is formed on the main surface 11a so as to cover the conductor pattern 12, the semiconductor element 20, the connecting material 23, the bonding wire 30, and the resist 40. The segmenting step S7 is performed after the resin sealing step S6. In the segmenting step S7, by dividing the substrate 10, a plurality of semiconductor devices 100 having the structure shown in FIGS. 1 to 3 are obtained.

### (Effects of Semiconductor Device 100)

Effects of the semiconductor device 100 will be described below in comparison with a semiconductor device according to a comparative example. A semiconductor device according to a first comparative example is referred to as a semiconductor device 100A, and a semiconductor device according to a second comparative example is referred to as a semiconductor device 100B.

The semiconductor device 100A includes a substrate 10, a semiconductor element 20, a bonding wire 30, a resist 40, and a sealing resin 50. In this regard, the configuration of the semiconductor device 100A is common to the configuration of the semiconductor device 100.

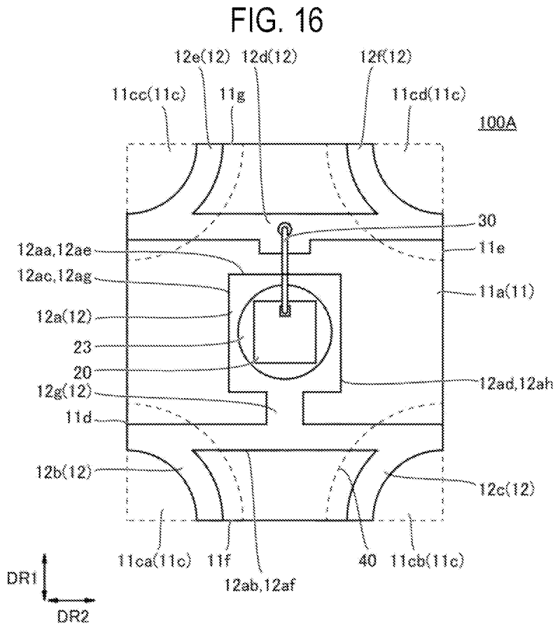

FIG. 16 is a plan view of the semiconductor device 100A. In FIG. 16, illustration of the sealing resin 50 is omitted, and the resist 40 is indicated by a dotted line. As shown in FIG. 16, the recess 12ai is not formed in the semiconductor device 100A. Furthermore, in the semiconductor device 100A, the conductor pattern 12 further includes a connection portion 12g. The connection portion 12g connects the second side 12af to the connection portions 12b and 12c. Regarding these points, the configuration of the semiconductor device 100A is different from the configuration of the semiconductor device 100.

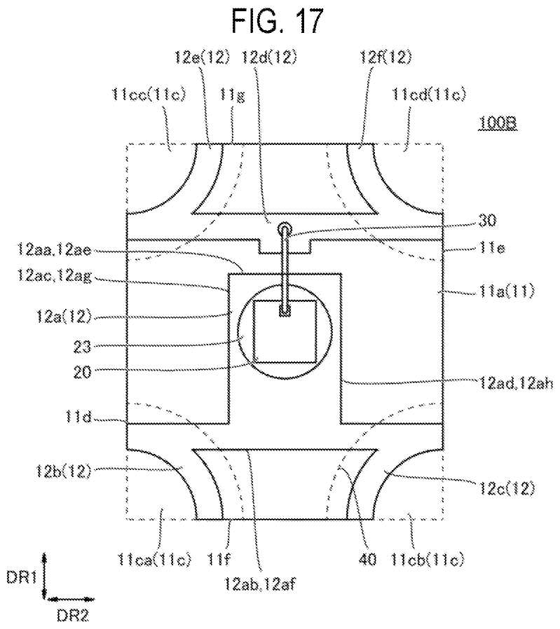

The semiconductor device 100B includes a substrate 10, a semiconductor element 20, a bonding wire 30, a resist 40, and a sealing resin 50. In this regard, the configuration of the semiconductor device 100B is common to the configuration of the semiconductor device 100. FIG. 17 is a plan view of the semiconductor device 100B. In FIG. 17, illustration of the sealing resin 50 is omitted, and the resist 40 is indicated by a dotted line. As shown in FIG. 17, the recess 12ai is not formed in the semiconductor device 100B. In this regard, the configuration of the semiconductor device 100B is common to the configuration of the semiconductor device 100.

In the semiconductor device 100A, a width of the die pad portion 12a in the first direction DR1 is smaller than that in the semiconductor device 100, such that misalignment of the semiconductor element 20 in the first direction DR1 is less likely to occur. However, in the semiconductor device 100A, a heat dissipation path from the die pad portion 12a to the connection portions 12b and 12c is narrowed at the connection portion 12g. Therefore, there is room for improvement in heat dissipation of the semiconductor element 20.

On the other hand, in the semiconductor device 100B, there is no narrow portion in a heat dissipation path from the die pad portion 12a. Therefore, heat dissipation of the semiconductor element 20 is improved as compared with the semiconductor device 100A. However, in the semiconductor device 100B, a width of the die pad portion 12a in the first direction DR1 is larger than that in the semiconductor device 100A. Therefore, misalignment of the semiconductor element 20 in the first direction DR1 is likely to occur. Such misalignment of the semiconductor element 20 causes a decrease in accuracy of a sensor 200 when the semiconductor device 100 is used in the sensor 200.

In the semiconductor device 100, the recess 12ai is formed, and the semiconductor element 20 is disposed between the bottom of the recess 12ai and the side facing the bottom in a plan view. Therefore, since a width of the die pad portion 12a in the first direction DR1 in which the semiconductor element 20 may be disposed is substantially reduced, the misalignment of the semiconductor element 20 is less likely to occur. Furthermore, in the semiconductor device 100, the recess 12ai is located at a position which is difficult to influence the heat dissipation path extending from the die pad portion 12a. Therefore, the recess 12ai hardly deteriorates the heat dissipation of the semiconductor element 20. As described above, according to the semiconductor device 100, it is possible to ensure the heat dissipation of the semiconductor element 20 while preventing the misalignment of the semiconductor element 20 in the first direction DR1.

In the method of manufacturing the semiconductor device 100, the recess 12ai may be formed simultaneously with the conductor pattern 12 when patterning the conductor layer 14. Thus, the manufacturing process does not become complicated due to the formation of the recess 12ai.

When the width W1 is 0.2 mm (0.15 mm) or less, the recess 12ai becomes less likely to affect the heat dissipation path extending from the die pad portion 12a, which makes it possible to further improve the heat dissipation of the semiconductor element 20. When the recess 12ai is formed on the second side 12af, it becomes easier to match the center of the semiconductor element 20 with the center of the base 11 in a plan view, which makes it possible to further improve the accuracy of the sensor 200 in which the semiconductor device 100 is used.

In a case where a value obtained by subtracting the width W2 from the distance DIS is less than 0.05 mm, the coated connecting material 23 may protrude from above the die pad portion 12a, thereby causing a short circuit between the die pad portion 12a and the bonding pad portion 12d. In a case where the value obtained by subtracting the width W2 from the distance DIS is larger than 0.40 mm, the width of the die pad portion 12a in the first direction DR1 in which the semiconductor element 20 may be disposed becomes larger than the width W2, and the misalignment of the semiconductor element 20 in the first direction DR1 is likely to occur. Therefore, in a case where the value obtained by subtracting the width W2 from the distance DIS is 0.05 mm or more and 0.40 mm or less, it is possible to prevent the misalignment of the semiconductor element 20 in the first direction DR1 while suppressing a short circuit between the die pad portion 12a and the bonding pad portion 12d.

### (Supplementary Note)

The embodiment of the present disclosure includes the following configurations.

### <Supplementary Note 1>

A semiconductor device including:
a substrate; and
a semiconductor element,
wherein the substrate includes a base and a conductor pattern arranged on the base,
wherein the conductor pattern includes a die pad portion, a first connection portion, and a second connection portion,
wherein the die pad portion includes a first end and a second end which are both ends in a first direction in a plan view, and a third end and a fourth end which are both ends in a second direction orthogonal to the first direction in the plan view,
wherein an outer periphery of the die pad portion includes a first side and a second side extending in the second direction in the plan view, and a third side and a fourth side extending in the first direction in a plan view,
wherein the first side and the second side constitute the first end and the second end, respectively,
wherein the third side and the fourth side constitute the third end and the fourth end, respectively,
wherein a recess is formed on one of the first side and the second side so as to be recessed toward the other of the first side and the second side,
wherein the first connection portion and the second connection portion are respectively connected to a first corner of the outer periphery of the die pad portion where the second side and the third side are joined, and a second corner of the outer periphery of the die pad portion where the second side and the fourth side are joined, and
wherein the semiconductor element is arranged on the die pad portion so as to be located between the first side or the second side and a bottom of the recess in the plan view.

### <Supplementary Note 2>

The semiconductor device of Supplementary Note 1, wherein the recess is formed on the second side.

### <Supplementary Note 3>

The semiconductor device of Supplementary Note 1, wherein a value obtained by subtracting a width of the semiconductor element in the first direction from a distance between the first side or the second side and the bottom of the recess in the first direction is 0.05 mm or more and 0.40 mm or less.

### <Supplementary Note 4>

The semiconductor device of any one of Supplementary Notes 1 to 3, wherein the recess is rectangular, triangular, or partially circular in the plan view.

### <Supplementary Note 5>

The semiconductor device of any one of Supplementary Notes 1 to 4, wherein the semiconductor element is an LED.

### <Supplementary Note 6>

A sensor comprising:
the semiconductor device of Supplementary Note 5; and
a light-receiving element,
wherein the light-receiving element is arranged to receive light from the LED.

### <Supplementary Note 7>

A method of manufacturing a semiconductor device, comprising:
preparing a substrate including a base and a conductor layer arranged on the base;
forming a conductor pattern including a die pad portion by patterning the conductor layer; and
mounting a semiconductor element on the die pad portion,
wherein the die pad portion includes a first end and a second end which are both ends in a first direction in a plan view,
wherein an outer periphery of the die pad portion includes a first side extending in a second direction orthogonal to the first direction in the plan view to constitute the first end, and a second side extending in the second direction to constitute the second end,
wherein when forming the die pad portion by patterning the conductor layer, a recess is formed on one of the first side and the second side so as to be recessed toward the other of the first side and the second side, and
wherein the semiconductor element is arranged so as to be located between the first side or the second side and a bottom of the recess in the plan view.

Although the embodiments of the present disclosure have been described above, the embodiments described above may be modified in various ways. Moreover, the scope of the present disclosure is not limited to the above-described embodiments. The scope of the present disclosure is defined by the claims, and is intended to include all changes within the meaning and scope equivalent to the claims.

According to the present disclosure in some embodiments, it is possible to ensure heat dissipation of a semiconductor element while preventing misalignment of the semiconductor element.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a substrate; and
a semiconductor element,
wherein the substrate includes a base and a conductor pattern arranged on the base,
wherein the conductor pattern includes a die pad portion, a first connection portion, and a second connection portion,
wherein the die pad portion includes a first end and a second end which are both ends in a first direction in a plan view, and a third end and a fourth end which are both ends in a second direction orthogonal to the first direction in the plan view,
wherein an outer periphery of the die pad portion includes a first side and a second side extending in the second direction in the plan view, and a third side and a fourth side extending in the first direction in the plan view,
wherein the first side and the second side constitute the first end and the second end, respectively,
wherein the third side and the fourth side constitute the third end and the fourth end, respectively,
wherein a recess is formed on one of the first side and the second side so as to be recessed toward the other of the first side and the second side,
wherein the first connection portion and the second connection portion are respectively connected to a first corner of the outer periphery of the die pad portion where the second side and the third side are joined, and a second corner of the outer periphery of the die pad portion where the second side and the fourth side are joined, and
wherein the semiconductor element is arranged on the die pad portion so as to be located between the first side or the second side and a bottom of the recess in the plan view.

2. The semiconductor device of claim 1, wherein the recess is formed on the second side.

3. The semiconductor device of claim 1, wherein a value obtained by subtracting a width of the semiconductor element in the first direction from a distance between the first side or the second side and the bottom of the recess in the first direction is 0.05 mm or more and 0.40 mm or less.

4. The semiconductor device of claim 1, wherein the recess is rectangular, triangular, or partially circular in the plan view.

5. The semiconductor device of claim 1, wherein the semiconductor element is an LED.

6. A sensor comprising:
the semiconductor device of claim 5; and
a light-receiving element,
wherein the light-receiving element is arranged to receive light from the LED.

7. A method of manufacturing a semiconductor device, comprising:
preparing a substrate including a base and a conductor layer arranged on the base;
forming a conductor pattern including a die pad portion by patterning the conductor layer; and
mounting a semiconductor element on the die pad portion,
wherein the die pad portion includes a first end and a second end which are both ends in a first direction in a plan view,
wherein an outer periphery of the die pad portion includes a first side extending in a second direction orthogonal to the first direction in the plan view to constitute the first end, and a second side extending in the second direction to constitute the second end,
wherein when forming the die pad portion by patterning the conductor layer, a recess is formed on one of the first side and the second side so as to be recessed toward the other of the first side and the second side, and
wherein the semiconductor element is arranged so as to be located between the first side or the second side and a bottom of the recess in the plan view.
